(19) United States
(12) Patent Application Publication
(10) Pub. No.: US 2014/0338191 A1
(43) Pub. Date: Nov. 20, 2014

(54) METHOD OF MANUFACTURING AN INTEGRATED TOUCH SENSOR WITH DECORATIVE COLOR GRAPHICS

(71) Applicant: Robert J. Petcavich, The Woodlands, TX (US)

(72) Inventor: Robert J. Petcavich, The Woodlands, TX (US)

(73) Assignee: UNI-PIXEL DISPLAYS, INC., The Woodlands, TX (US)

(21) Appl. No.: 13/894,616

(22) Filed: May 15, 2013

(51) Int. Cl. H05K 3/10

(52) U.S. Cl. CPC H05K 3/10
USPC 29/846; 427/58; 427/551; 427/123

(57) ABSTRACT

A method of manufacturing includes printing a first plurality of patterned ink seed layers on a first side of a substrate. A second plurality of patterned ink seed layers are printed on a second side of the substrate. The first plurality of patterned ink seed layers and the second plurality of patterned ink seed layers are electroless plated with a first conductive material. A coating is printed over the first side of the substrate. A graphic design is printed on the second side of the substrate.

### BACKGROUND OF THE INVENTION

An electronic device with a touch screen allows a user to control the device by touch. The user may interact directly with the objects depicted on the display through touch or gestures. Touch screens are commonly found in consumer, commercial, and industrial devices including smartphones, tablets, laptop computers, desktop computers, monitors, gaming consoles, and televisions. A touch screen includes a touch sensor that includes a pattern of conductive lines disposed on a substrate.

Flexographic printing is a rotary relief printing process that transfers an image to a substrate. A flexographic printing process may be adapted for use in the fabrication of touch sensors. In addition, a flexographic printing process may be adapted for use in the fabrication of flexible and printed electronics (“FPE”).

### BRIEF SUMMARY OF THE INVENTION

According to one aspect of one or more embodiments of the present invention, a method of manufacturing includes printing a first plurality of patterned ink seed layers on a first side of a substrate. A second plurality of patterned ink seed layers are printed on a second side of the substrate. The first plurality of patterned ink seed layers and the second plurality of patterned ink seed layers are electroless plated with a first conductive material. A coating is printed over the first side of the substrate. A graphic design is printed on the second side of the substrate.

According to one aspect of one or more embodiments of the present invention, a method of manufacturing includes printing a coating over a first side of a first substrate. A graphic design is printed on a second side of the first substrate. A first plurality of patterned ink seed layers are printed on a first side of a second substrate. A second plurality of patterned ink seed layers are printed on a second side of the second substrate. The first plurality of patterned ink seed layers and the second plurality of patterned ink seed layers of the second substrate are electroless plated with a first conductive material. The first substrate is laminated to the second substrate.

According to one aspect of one or more embodiments of the present invention, a method of manufacturing includes printing a coating over a first side of a first substrate. A first plurality of patterned ink seed layers are printed on a second side of the first substrate. The first plurality of patterned ink seed layers of the first substrate are electroless plated with a first conductive material. A graphic design is printed on the second side of the first substrate. A second plurality of patterned ink seed layers are printed on a first side of a second substrate. The second plurality of patterned ink seed layers of the second substrate are electroless plated with the first conductive material. The first substrate is laminated to the second substrate.

Other aspects of the present invention will be apparent from the following description and claims.

### BRIEF DESCRIPTION OF THE DRAWINGS

FIG. 1 shows a portion of a conductive pattern design on a flexible and transparent substrate having junctions between lines or features of different widths or orientations in accordance with one or more embodiments of the present invention.

FIG. 2 shows a flexographic printing station in accordance with one or more embodiments of the present invention.

FIG. 3 shows a multi-station flexographic printing system in accordance with one or more embodiments of the present invention.

FIG. 4 shows a cross-sectional view of a single-substrate integrated touch sensor in accordance with one or more embodiments of the present invention.

FIG. 5 shows a top view of a single-substrate integrated touch sensor in accordance with one or more embodiments of the present invention.

FIG. 6 shows a method of manufacturing a single-substrate integrated touch sensor in accordance with one or more embodiments of the present invention.

FIGS. 7A-7C show a cross-sectional view of a two-substrate laminated touch sensor in accordance with one or more embodiments of the present invention.

FIG. 8 shows a method of manufacturing a two-substrate laminated touch sensor in accordance with one or more embodiments of the present invention.

FIG. 9A-9C show a cross-sectional view of a two-substrate laminated touch sensor in accordance with one or more embodiments of the present invention.

FIG. 10 shows a method of manufacturing a two-substrate laminated touch sensor in accordance with one or more embodiments of the present invention.

### DETAILED DESCRIPTION OF THE INVENTION

One or more embodiments of the present invention are described in detail with reference to the accompanying figures. For consistency, like elements in the various figures are denoted by like reference numerals. In the following detailed description of the present invention, specific details are set forth in order to provide a thorough understanding of the present invention. In other instances, well-known features to one of ordinary skill in the art are not described to avoid obscuring the description of the present invention.

A conventional flexographic printing system uses a flexographic printing plate, sometimes referred to as a flexo master, to transfer an image to a substrate. The flexographic printing plate includes one or more embossing patterns, or raised projections, that have distal ends onto which ink or other material may be deposited. In operation, the inked flexographic printing plate transfers an ink image of the one or more embossing patterns to the substrate.

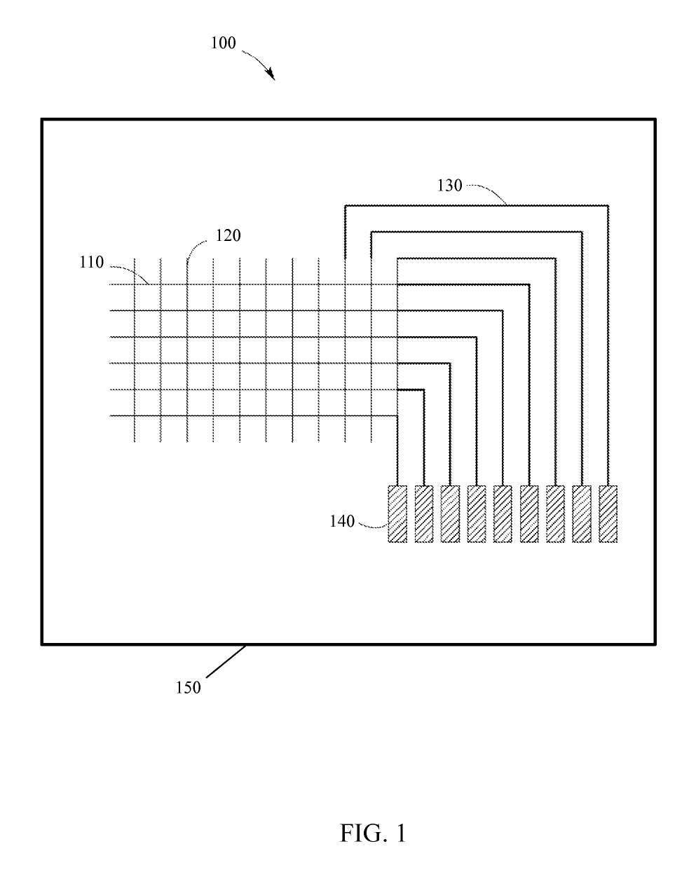

FIG. 1 shows a portion of a conductive pattern design on a flexible and transparent substrate having junctions between conductive lines or features of different widths or orientations in accordance with one or more embodiments of the present invention. Two or more conductive pattern designs 100 may form a projected capacitance touch sensor (not independently illustrated). In certain embodiments, conductive pattern design 100 may include a micro-mesh formed by a plurality of parallel x-axis conductive lines 110 and a plurality of parallel y-axis conductive lines 120 disposed on substrate 150. X-axis conductive lines 110 may be perpendicular or angled relative to y-axis conductive lines 120. A plurality of interconnect conductive lines 130 may route x-axis conductive lines 110 and y-axis conductive lines 120 to connector conductive lines 140. A plurality of connector conductive lines 140 may be configured to provide a connection to an interface (not shown) to a touch sensor controller (not shown) that detects touch through the touch sensor (not shown).

In certain embodiments, one or more of x-axis conductive lines 110, y-axis conductive lines 120, interconnect conductive lines 130, and connector conductive lines 140 may have different line widths or different orientations. The number of x-axis conductive lines 110, the line-to-line spacing between x-axis conductive lines 110, the number of y-axis conductive lines 120, and the line-to-line spacing between y-axis conductive lines 120 may vary based on an application. One of ordinary skill in the art will recognize that the size, configuration, and design of conductive pattern design 100 may vary in accordance with one or more embodiments of the present invention.

In one or more embodiments of the present invention, one or more of x-axis conductive lines 110 and one or more of y-axis conductive lines 120 may have a line width less than approximately 10 micrometers. In one or more embodiments of the present invention, one or more of x-axis conductive lines 110 and one or more of y-axis conductive lines 120 may have a line width in a range between approximately 10 micrometers and approximately 50 micrometers. In one or more embodiments of the present invention, one or more of x-axis conductive lines 110 and one or more of y-axis conductive lines 120 may have a line width greater than approximately 50 micrometers. One of ordinary skill in the art will recognize that the shape and width of one or more x-axis conductive lines 110 and one or more y-axis conductive lines 120 may vary in accordance with one or more embodiments of the present invention.

In one or more embodiments of the present invention, one or more of interconnect conductive lines 130 may have a line width in a range between approximately 50 micrometers and approximately 100 micrometers. One of ordinary skill in the art will recognize that the shape and width of one or more interconnect conductive lines 130 may vary in accordance with one or more embodiments of the present invention. In one or more embodiments of the present invention, one or more of connector conductive lines 140 may have a line width greater than approximately 100 micrometers. One of ordinary skill in the art will recognize that the shape and width of one or more connector conductive lines 140 may vary in accordance with one or more embodiments of the present invention.

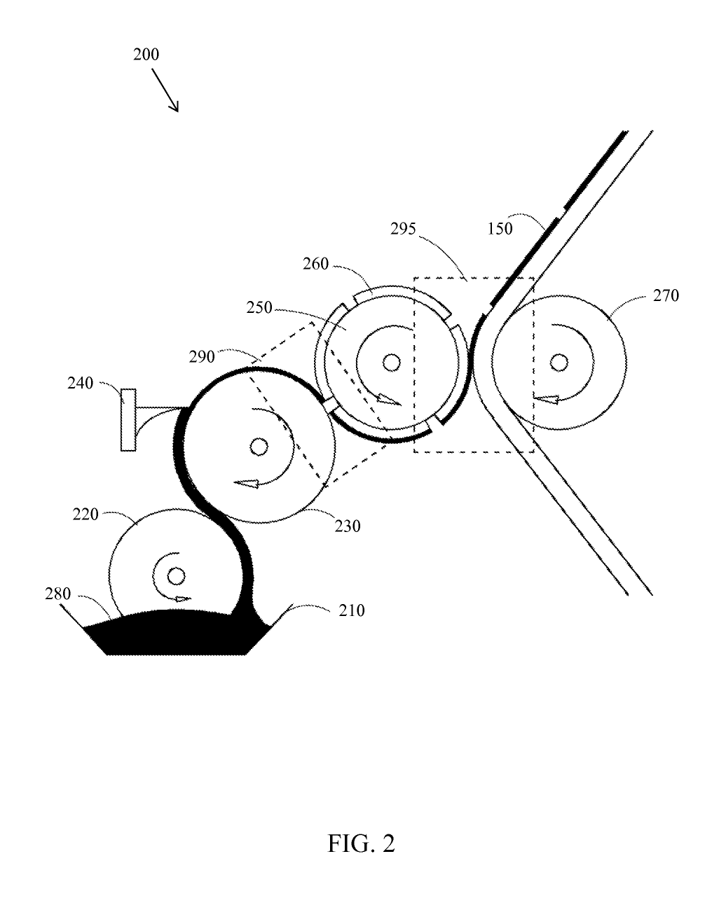

FIG. 2 shows a flexographic printing station in accordance with one or more embodiments of the present invention. Flexographic printing station 200 may include an ink pan 210, an ink roll 220 (also referred to as a fountain roll), an anilox roll 230 (also referred to as a meter roll), a doctor blade 240, a printing plate cylinder 250, a flexographic printing plate 260, and an impression cylinder 270.

In operation, ink roll 220 transfers ink 280 from ink pan 210 to anilox roll 230. In certain embodiments, ink 280 may be a catalytic ink or catalytic alloy ink that serves as a plating seed suitable for metallization by electroless plating. In other embodiments, ink 280 may be a colored ink suitable for a decorative graphic design. One of ordinary skill in the art will recognize that the composition of ink 280 may vary in accordance with one or more embodiments of the present invention. Anilox roll 230 is typically constructed of a steel or aluminum core coated by an industrial ceramic whose surface contains a plurality of very fine dimples, known as cells (not shown). Doctor blade 240 removes excess ink 280 from anilox roll 230. In transfer area 290, anilox roll 230 meters the amount of ink 280 transferred to flexographic printing plate 260 to a uniform thickness. Printing plate cylinder 250 is typically made of metal and the surface may be plated with chromium, or the like, to provide increased abrasion resistance. Flexographic printing plate 260 may be mounted to printing plate cylinder 250 by an adhesive (not shown).

Substrate 150 moves between printing plate cylinder 250 and impression cylinder 270. In certain embodiments, substrate 150 may be flexible and transparent. Transparent means the transmission of visible light with a transmittance rate of 85% or more. In one or more embodiments of the present invention, substrate 150 may be polyethylene terephthalate (“PET”), polyethylene naphthalate (“PEN”), cellulose acetate (“TAC”), acrylic, epoxy, polyimide, polyurethane, polycarbonate, cycloolefin polymers, glass, or combinations thereof. One of ordinary skill in the art will recognize that the composition of substrate 150 may vary in accordance with one or more embodiments of the present invention. Impression cylinder 270 applies pressure to printing plate cylinder 250, transferring an image from embossing patterns of flexographic printing plate 160 onto substrate 150 at transfer area 295. The rotational speed of printing plate cylinder 250 is synchronized to match the speed at which substrate 150 moves through flexographic printing system 200. In certain embodiments, the speed may vary between 20 feet per minute to 750 feet per minute.

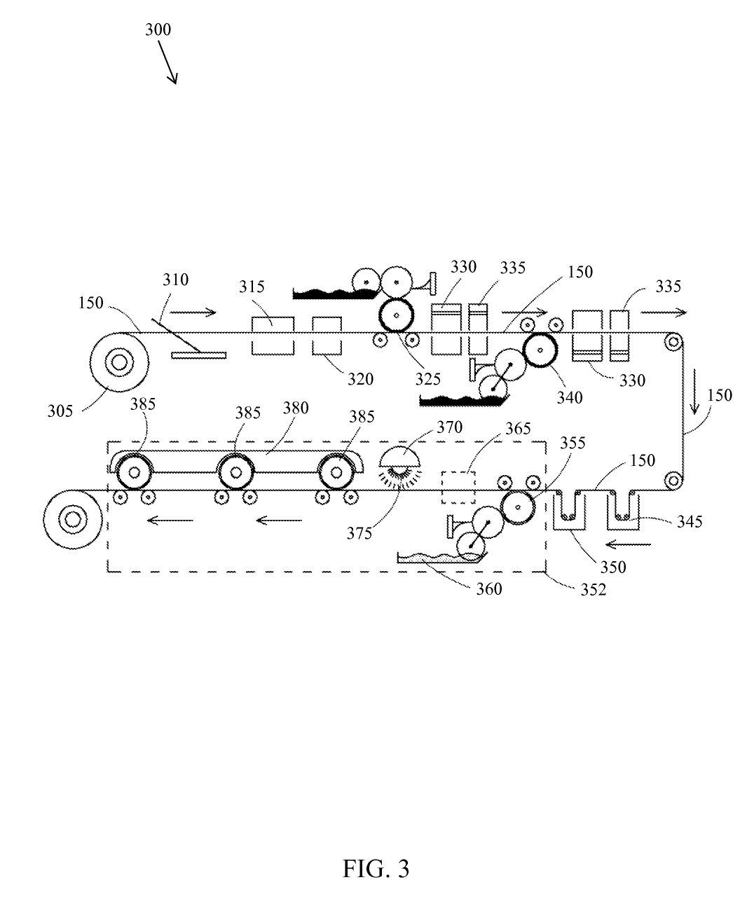

FIG. 3 shows a multi-station flexographic printing system 300 in accordance with one or more embodiments of the present invention. Multi-station flexographic printing system 300 may be configured to manufacture a single-substrate integrated touch sensor (not shown) in a single manufacturing pass. Substrate 150 may be a flexible, transparent, and continuous substrate suitable for use with a roll-to-roll flexographic printing system. In certain embodiments, substrate 150 may be PET, PEN, TAC, acrylic, epoxy, polyimide, polyurethane, polycarbonate, cycloolefin polymers, glass, or combinations thereof. Substrate 150 may have a thickness small enough to provide the appropriate flexibility and transparency of a single-substrate integrated touch sensor (not shown) and large enough to provide the required functionality and reliability. In certain embodiments, substrate 150 may have a thickness in a range between approximately 1 micrometer and approximately 1 millimeter. One of ordinary skill in the art will recognize that the thickness of substrate 150 may vary in accordance with one or more embodiments of the present invention based on the application.

Substrate 150 may be placed on an unwinding roll 305 configured to feed substrate 150 to system 300. Substrate 150 may proceed through an alignment module 310 configured to align substrate 150 after unwinding. In certain embodiments, alignment module 310 may be a cable positioner. In other embodiments, alignment module 310 may be a feed-through guide. One of ordinary skill in the art will recognize that alignment module 310 may be any device suitable for aligning substrate 150 after unwinding. Substrate 150 may proceed through a first cleaning module 315 configured to remove impurities, such as oil or grease, from the surface of substrate 150 prior to printing, if necessary. In certain embodiments, first cleaning module 315 may be a high electric field ozone generator. In other embodiments, first cleaning module 315 may be a deionized air shower. Substrate 150 may continue through a second cleaning module 320 configured to remove particulate matter, contaminants, and other impurities, if necessary. In certain embodiments, second cleaning module 320 may be a web cleaner. In other embodiments, second cleaning module 320 may be a deionized air shower.

After cleaning, substrate 150 may proceed through one or more flexographic printing stations 325 configured to print on a first side of substrate 150. Each flexographic printing station 325 may be flexographic printing station 200 of FIG. 2. One or more flexographic printing stations 325 may print a first plurality of patterned ink seed layers (not shown) on the first side of substrate 150. The first plurality of patterned ink seed layers (not shown) may include a plurality of x-axis seed lines (not shown), a plurality of y-axis seed lines (not shown), a plurality of interconnect seed lines (not shown), and a plurality of connector seed lines (not shown). In one or more embodiments of the present invention, one or more of the plurality of x-axis seed lines (not shown) and one or more of the plurality of y-axis seed lines (not shown) may have a width less than 10 micrometers.

In certain embodiments, a separate flexographic printing station 325 may be used to print one or more of the x-axis seed lines (not shown), y-axis seed lines (not shown), interconnect seed lines (not shown), and connector seed lines (not shown) on the first side of substrate 150. For example, in certain embodiments, a first flexographic printing station 325 may be used to print the plurality of x-axis seed lines (not shown), a second flexographic printing station 325 may be used to print the plurality of y-axis seed lines (not shown), a third flexographic printing station 325 may be used to print the plurality of interconnect seed lines (not shown), and a fourth flexographic printing station 325 may be used to print the plurality of connector seed lines (not shown) in a predetermined sequence. In other embodiments, the third flexographic printing station 325 may be used to print the plurality of interconnect seed lines (not shown) and the plurality of connector seed lines (not shown). One of ordinary skill in the art will recognize that the number of flexographic printing stations 325 used to print on the first side of substrate 150 may vary in accordance with one or more embodiments of the present invention. In certain embodiments, the flexographic printing stations 325 may be sequenced to print smaller lines or features before larger lines or features. The first plurality of patterned ink seed layers (not shown) may be printed by one or more flexographic printing stations 325 with a catalytic ink or catalytic alloy ink (280 of FIG. 2). As a result, the first plurality of patterned ink seed layers (not shown) may serve as plating seed lines (not shown) suitable for metallization by electroless plating.

After printing, substrate 150 may proceed through a curing module 330 configured to polymerize the printed first plurality of patterned ink seed layers (not shown). In certain embodiments, curing module 330 may be UV radiation with a wavelength in a range between approximately 280 nanometers and 480 nanometers with target intensity in a range between approximately 0.5 mW/cm² and approximately 50 mW/cm² with an exposure time in a range between approximately 0.1 seconds to approximately 5 seconds. Substrate 150 may continue through a soft-bake module 335 configured to finalize the curing process. In certain embodiments, soft-bake module 335 may be a pass-through oven that applies heat in a temperature range between approximately 20 degrees Celsius and approximately 85 degrees Celsius for a period of time in a range between approximately 1 second to approximately 10 seconds.

Substrate 150 may proceed through one or more flexographic printing stations 340 configured to print on a second side of substrate 150. Each flexographic printing station 340 may be flexographic printing station 200 of FIG. 2. One or more flexographic printing stations 340 may print a second plurality of patterned ink seed layers (not shown) on the second side of substrate 150. The second plurality of patterned ink seed layers (not shown) may include a plurality of x-axis seed lines (not shown), a plurality of y-axis seed lines (not shown), a plurality of interconnect seed lines (not shown), and a plurality of connector seed lines (not shown). In one or more embodiments of the present invention, one or more of the plurality of x-axis seed lines (not shown) and one or more of the plurality of y-axis seed lines (not shown) may have a width less than 10 micrometers.

In certain embodiments, a separate flexographic printing station 340 may be used to print one or more of the x-axis seed lines (not shown), y-axis seed lines (not shown), interconnect seed lines (not shown), and connector seed lines (not shown) on the second side of substrate 150. For example, in certain embodiments, a first flexographic printing station 340 may be used to print the plurality of x-axis seed lines (not shown), a second flexographic printing station 340 may be used to print the plurality of y-axis seed lines (not shown), a third flexographic printing station 340 may be used to print the plurality of interconnect seed lines (not shown), and a fourth flexographic printing station 340 may be used to print the plurality of connector seed lines (not shown) in a predetermined sequence. In other embodiments, the third flexographic printing station 340 may be used to print the plurality of interconnect seed lines (not shown) and the plurality of connector seed lines (not shown). One of ordinary skill in the art will recognize that the number of flexographic printing stations 340 used to print on the second side of substrate 150 may vary in accordance with one or more embodiments of the present invention. In certain embodiments, the flexographic printing stations 340 may be sequenced to print smaller lines or features before larger lines or features. The second plurality of patterned ink seed layers (not shown) may be printed by one or more flexographic printing stations 340 with a catalytic ink or catalytic alloy ink (280 of FIG. 2). As a result, the second plurality of patterned ink seed layers (not shown) serve as plating seed lines (not shown) suitable for metallization by electroless plating.

After printing, substrate 150 may proceed through another curing module 330 configured to polymerize the printed second plurality of patterned ink seed layers (not shown). In certain embodiments, curing module 330 may be UV radiation with a wavelength in a range between approximately 280 nanometers and 480 nanometers with target intensity in a range between approximately 0.5 mW/cm² and approximately 50 mW/cm² with an exposure time in a range between approximately 0.1 seconds and approximately 5 seconds. Substrate 150 may proceed through another soft-bake module 335 configured to finalize the curing process. In certain embodiments, soft-bake module 335 may be a pass-through oven that applies heat in a temperature range between approximately 20 degrees Celsius and approximately 85 degrees Celsius for a period of time in a range between approximately 1 second to approximately 10 seconds.

Substrate 150 may proceed through electroless plating module 345 configured to electroless plate a first conductive material (not shown) on the first and second plurality of patterned ink seed layers (not shown). Substrate 150 may be submerged in electroless plating module 345 that includes a first conductive material in a liquid state at a temperature in a range between approximately 20 degrees Celsius and approximately 90 degrees Celsius. In certain embodiments, the first conductive material is in a liquid state at a temperature of approximately 45 degrees Celsius. In certain embodiments, the first conductive material may be composed of copper. In other embodiments, the first conductive material may be composed of a copper alloy. One of ordinary skill in the art will recognize that the first conductive material may be composed of other metals or metal alloys in accordance with one or more embodiments of the present invention. In electroless plating module 345, the deposition rate on top of the first and second plurality of patterned ink seed layers (not shown) may be approximately 10 nanometers per minute of first conductive material (not shown) with a deposited thickness in a range between approximately 0.001 micrometers and approximately 10 micrometers. Electroless plating module 345 does not require the application of an electrical current and only plates the first and second plurality of patterned ink seed layers (not shown) that were previously printed and cured.

In certain embodiments, substrate 150 may proceed through another electroless plating module 345 (not shown) configured to electroless plate a second conductive material (not shown) on the plated first and second plurality of patterned ink seed layers (not shown). Substrate 150 may be submerged in electroless plating module 345 that includes a second conductive material in a liquid state at a temperature in a range between approximately 20 degrees Celsius and approximately 90 degrees Celsius. In certain embodiments, the second conductive material is in a liquid state at a temperature of approximately 80 degrees Celsius. In certain embodiments, the second conductive material may be composed of nickel. In other embodiments, the second conductive material may be composed of a nickel alloy. One of ordinary skill in the art will recognize that the second conductive material may be composed of other metals or metal alloys in accordance with one or more embodiments of the present invention. In electroless plating module 345, the deposition rate on top of the plated first and second plurality of patterned ink seed layers (not shown) may be approximately 10 nanometers per minute of second conductive material (not shown) with a deposited thickness in a range between approximately 0.001 micrometers and approximately 10 micrometers. Electroless plating module 345 does not require the application of an electrical current and only plates the plated first and second plurality of patterned ink seed layers (not shown) that were previously printed, cured, and plated with the first conductive material.

Substrate 150 may proceed through a cleaning module 350 configured to clean substrate 150 after electroless plating. In certain embodiments, cleaning module 350 may be a water tank that contains water at room temperature. After washing substrate 150, cleaning module 350 may dry substrate 150 through the application of air at room temperature. In certain embodiments, a passivation agent (not shown) may be sprayed on substrate 150 to prevent an undesired chemical reaction between the conductive materials and the water.

Substrate 150 may proceed through a coating and graphic module 352. Substrate 150 may proceed through a flexographic printing station 355 configured to print a coating 360 over the first side of substrate 150. Flexographic printing station 355 may be flexographic printing station 200 of FIG. 2. Flexographic printing station 355 may utilize a blank flexographic printing plate (260 of FIG. 2) that does not include engraved embossing patterns. During the flexographic printing process, flexographic printing station 355 may print a conformal layer of coating 360, instead of ink, over the first side of substrate 150. In certain embodiments, coating 360 may have a thickness in a range between approximately 1 micrometer and approximately 50 micrometers over the plated first plurality of patterned ink seed layers. In one or more embodiments of the present invention, coating 360 may be composed of a scratch and abrasion resistant coating material. In certain embodiments, coating 360 may be composed of solid content, such as multifunctional monomers and oligomers, with a concentration by weight in a range between approximately 70% and approximately 80%, a photo-initiator with a concentration by weight in a range between approximately 1% and approximately 6%, and a solvent with a concentration by weight in a range between approximately 10% and approximately 30%. In one or more embodiments of the present invention, coating 360 may be scratch and abrasion resistant and may provide a pencil hardness of at least 6H.

Substrate 150 may proceed through a transition zone 365 having a temperature in a range between approximately 20 degrees Celsius and 30 degrees Celsius for a period of time in a range between approximately 5 seconds and approximately 300 seconds. Transition zone 365 allows for a proper wetting of coating 360 on the surface of the first side of substrate 150. Substrate 150 may then proceed through a curing module 370 configured to cure coating 360 on substrate 150 in an oxygen free zone. Curing module 370 may include UV radiation 375 with a wavelength in a range between approximately 280 nanometers and 480 nanometers and target intensity in a range between approximately 0.5 mW/cm² and approximately 20 mW/cm² with an exposure time in a range between approximately 0.1 seconds and approximately 5 seconds. The curing speed may be important to obtain a proper cross-linked density of coating 360. The reaction of monomers into a cross-linked polymer structure may occur in a relatively short period of time while coating 360 is in a liquid state.

Finally, substrate 150 may proceed through a color graphics printing module 380 configured to print a graphic design (not shown) on the second side of substrate 150. Color graphics printing module 380 may include one or more color graphics printing stations 385. In certain embodiments, color graphics printing stations 385 may be flexographic printing stations 340 that use color ink. In one or more embodiments of the present invention, the graphic design (not shown) may be printed in a frame area (not shown) surrounding the plated second plurality of patterned ink seed layers. The graphic design (not shown) may be any decorative graphic design suitable for flexographic printing. In certain embodiments, each of the one or more color graphics printing stations 385 may print a unique color to achieve a multi-color graphic design. In other embodiments, each of the one or more color graphics printing stations 385 may print the same color to provide redundancy and reduce light transmission through the graphic design. After completion through multi-station flexographic printing system 300, substrate 150 may be removed from the roll and configured for use as a single-substrate integrated touch sensor with decorative color graphics.

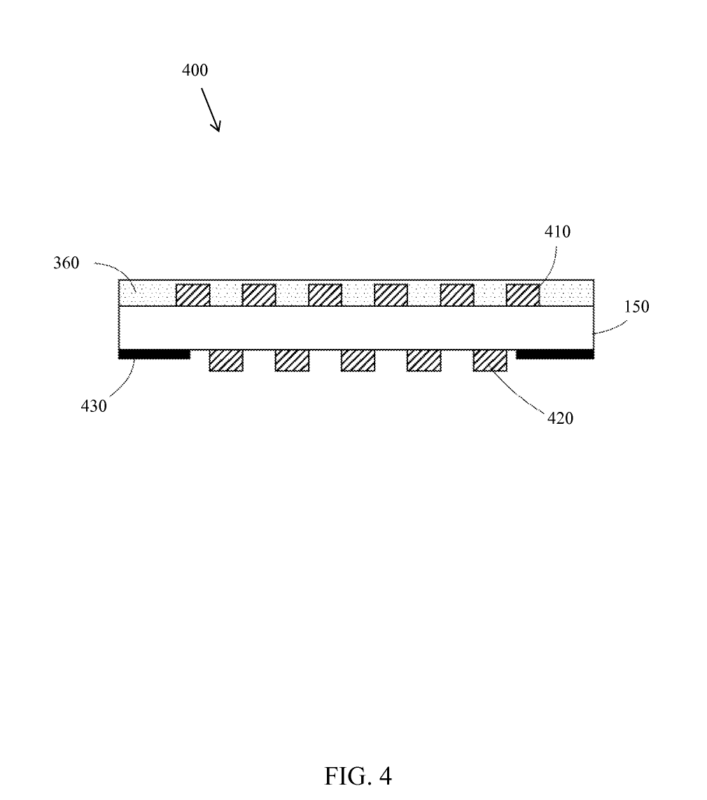

FIG. 4 shows a cross-sectional view of a single-substrate integrated touch sensor 400 in accordance with one or more embodiments of the present invention. In certain embodiments, touch sensor 400 may be manufactured by multi-station flexographic printing system 300 of FIG. 3. A first side of substrate 150 may include a first plurality of conductive lines 410 formed by the plated first plurality of patterned ink seed layers. In one or more embodiments of the present invention, the plurality of conductive lines 410 may include one or more of x-axis conductive lines, y-axis conductive lines, interconnect conductive lines, and connector conductive lines. In certain embodiments, the plurality of conductive lines 410 may form a conductive pattern design (100 of FIG. 1) on the first side of substrate 150 as part of touch sensor 400. A coating 360 may be disposed over the first side of substrate 150. Coating 360 may be composed of a scratch and abrasion resistant coating material that has a pencil hardness of at least 6H.

A second side of substrate 150 may include a plurality of conductive lines 420 formed by the plated second plurality of patterned ink seed layers. In one or more embodiments of the present invention, the plurality of conductive lines 420 may include one or more of x-axis conductive lines, y-axis conductive lines, interconnect conductive lines, and connector conductive lines. In certain embodiments, the plurality of conductive lines 420 may form a conductive pattern design (100 of FIG. 1) on the second side of the substrate 150 as part of touch sensor 400. A graphic design 430 may be disposed in a frame area of touch sensor 400 surrounding the plurality of conductive lines 420. In operation, the first side of touch sensor 400, which includes coating 360, faces a user. Because substrate 150 is transparent, graphic design 430, disposed on the second side of substrate 150, is visible to the user facing the first side of substrate 150. As such, graphic design 430 may be viewed through substrate 150. Because graphic design 430 is disposed on the second side of substrate 150, when the user interacts with touch sensor 400, the graphic design 430 is not subjected to wear from repeated use.

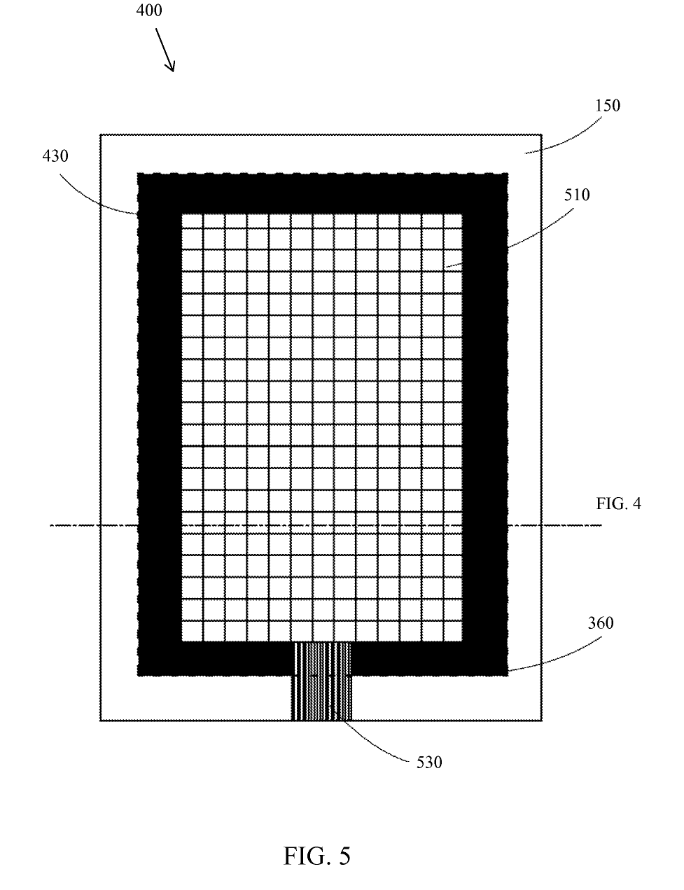

FIG. 5 shows a top view of a single-substrate integrated touch sensor 400 in accordance with one or more embodiments of the present invention. Touch sensor 400 includes a projected capacitance touch sensor circuit 510 formed by the plurality of conductive lines (410 and 420 of FIG. 4) disposed on both sides of substrate 150, including connector conductive lines 530 that provide an interface between touch sensor 400 and a touch sensor controller (not shown). A coating 360 may cover the first side of substrate 150 facing the user in this top view of touch sensor 400 and provide a scratch and abrasion resistant point of contact for the user. A graphic design 430 may be disposed on the second side of substrate 150. Because substrate 150 is transparent, graphic design 430 may be visible through substrate 150 to the user in this top view of touch sensor 400.

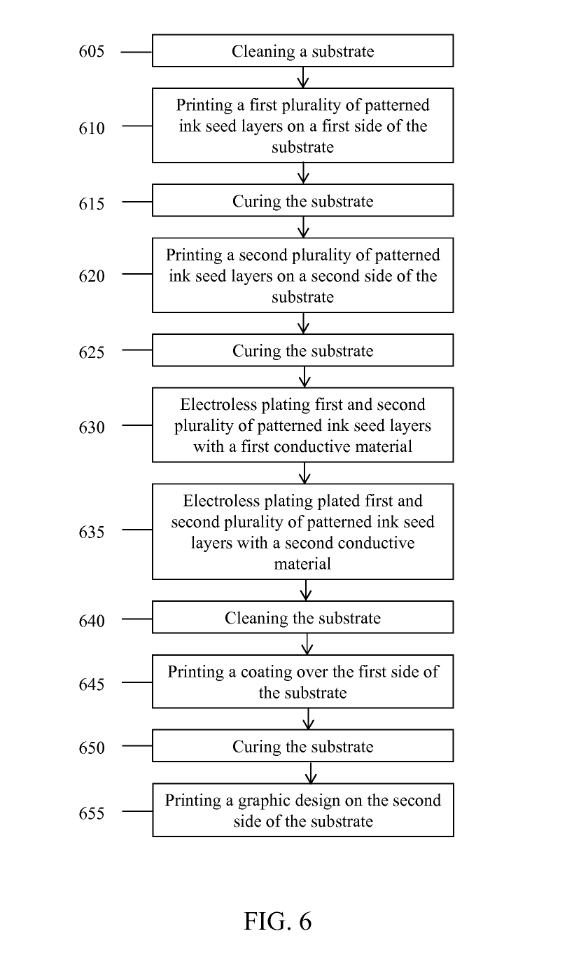

FIG. 6 shows a method of manufacturing a single-substrate integrated touch sensor 400 in accordance with one or more embodiments of the present invention. In certain embodiments, touch sensor 400 may be manufactured by multi-station flexographic printing system 300 of FIG. 3.

In step 605, a substrate may be cleaned to prepare it for flexographic printing. The substrate may be a flexible and transparent substrate composed of PET, PEN, TAC, acrylic, epoxy, polyimide, polyurethane, polycarbonate, cycloolefin polymers, glass, or combinations thereof. In certain embodiments, the substrate may have a thickness in a range between approximately 1 micrometer and approximately 1 millimeter. In certain embodiments, the substrate may be cleaned with a high electric field ozone generator configured to remove impurities, such as oil or grease, from the surface of the substrate prior to printing. In other embodiments, the substrate may be cleaned with a deionized air shower. The substrate may also be cleaned by a web cleaner configured to remove particulate matter, contaminants, and other impurities. One of ordinary skill in the art will recognize that the substrate may be cleaned by other processes in accordance with one or more embodiments of the present invention.

In step 610, a first plurality of patterned ink seed layers may be printed on a first side of the substrate. The first plurality of patterned ink seed layers may include a plurality of x-axis seed lines, a plurality of y-axis seed lines, a plurality of interconnect seed lines, and a plurality of connector seed lines. In one or more embodiments of the present invention, one or more of the plurality of x-axis seed lines and one or more of the plurality of y-axis seed lines may have a width less than 10 micrometers. In certain embodiments, one or more of x-axis seed lines, y-axis seed lines, interconnect seed lines, and connector seed lines may be printed by a separate flexographic printing station. For example, in certain embodiments, a first flexographic printing station may be used to print the plurality of x-axis seed lines, a second flexographic printing station may be used to print the plurality of y-axis seed lines, a third flexographic printing station may be used to print the plurality of interconnect seed lines, and a fourth flexographic printing station may be used to print the plurality of connector seed lines in a predetermined sequence. In other embodiments, the third flexographic printing station may be used to print the plurality of interconnect seed lines and the plurality of connector seed lines. One of ordinary skill in the art will recognize that the number of flexographic printing stations used to print on the first side of the substrate may vary in accordance with one or more embodiments of the present invention. In certain embodiments, the flexographic printing stations may be sequenced to print smaller lines or features before larger lines or features. The first plurality of patterned ink seed layers may be printed with a catalytic ink or catalytic alloy ink. As a result, the first plurality of patterned ink seed layers may serve as plating seed lines suitable for metallization by an electroless plating process.

In step 615, the substrate may be cured to polymerize the printed first plurality of patterned ink seed layers on the first side of the substrate. The substrate may be cured by UV radiation with a wavelength in a range between approximately 280 nanometers and 480 nanometers with target intensity in a range between approximately 0.5 mW/cm² and approximately 50 mW/cm² with an exposure time in a range between approximately 0.1 seconds and approximately 5 seconds. As part of curing, the substrate may then be soft-baked in a pass-through oven that applies heat in a temperature range between approximately 20 degrees Celsius and approximately 85 degrees Celsius for a period of time in a range between approximately 1 second to approximately 10 seconds.

In step 620, a second plurality of patterned ink seed layers may be printed on a second side of the substrate. The second plurality of patterned ink seed layers may include a plurality of x-axis seed lines, a plurality of y-axis seed lines, a plurality of interconnect seed lines, and a plurality of connector seed lines. In one or more embodiments of the present invention, one or more of the plurality of x-axis seed lines and one or more of the plurality of y-axis seed lines may have a width less than 10 micrometers. In certain embodiments, one or more of x-axis seed lines, y-axis seed lines, interconnect seed lines, and connector seed lines may be printed by a separate flexographic printing station. For example, in certain embodiments, a first flexographic printing station may be used to print the plurality of x-axis seed lines, a second flexographic printing station may be used to print the plurality of y-axis seed lines, a third flexographic printing station may be used to print the plurality of interconnect seed lines, and a fourth flexographic printing station may be used to print the plurality of connector seed lines in a predetermined sequence. In other embodiments, the third flexographic printing station may be used to print the plurality of interconnect seed lines and the plurality of connector seed lines. One of ordinary skill in the art will recognize that the number of flexographic printing stations used to print on the first side of substrate may vary in accordance with one or more embodiments of the present invention. In certain embodiments, the flexographic printing stations may be sequenced to print smaller lines or features before larger lines or features. The second plurality of patterned ink seed layers may be printed with a catalytic ink or catalytic alloy ink. As a result, the second plurality of patterned ink seed layers may serve as plating seed lines suitable for metallization by an electroless plating process.

In step 625, the substrate may be cured to polymerize the printed second plurality of patterned ink seed layers on the second side of the substrate. The substrate may be cured by UV radiation with a wavelength in a range between approximately 280 nanometers and 480 nanometers with target intensity in a range between approximately 0.5 mW/cm² and approximately 50 mW/cm² with an exposure time in a range between approximately 0.1 seconds and approximately 5 seconds. As part of curing, the substrate may then be soft-baked in a pass-through oven that applies heat in a temperature range between approximately 20 degrees Celsius and approximately 85 degrees Celsius for a period of time in a range between approximately 1 second to approximately 10 seconds.

In step 630, the first plurality of patterned ink seed layers and the second plurality of patterned ink seed layers may be electroless plated with a first conductive material. The substrate may be submerged in an electroless plating tank that includes a first conductive material in a liquid state at a temperature in a range between approximately 20 degrees Celsius and approximately 90 degrees Celsius. In certain embodiments, the first conductive material may be in a liquid state at a temperature of approximately 45 degrees Celsius. In certain embodiments, the first conductive material may be composed of copper. In other embodiments, the first conductive material may be composed of a copper alloy. One of ordinary skill in the art will recognize that the first conductive material may be composed of other metals or metal alloys in accordance with one or more embodiments of the present invention. The deposition rate on top of the first and second plurality of patterned ink seed layers may be approximately 10 nanometers per minute of first conductive material with a deposited thickness in a range between approximately 0.001 micrometers and approximately 10 micrometers.

In step 635, the plated first plurality of patterned ink seed layers and the plated second plurality of patterned ink seed layers may be electroless plated with a second conductive material. The substrate may be submerged in an electroless plating tank that includes a second conductive material in a liquid state at a temperature in a range between approximately 20 degrees Celsius and approximately 90 degrees Celsius. In certain embodiments, the second conductive material may be in a liquid state at a temperature of approximately 45 degrees Celsius. In certain embodiments, the second conductive material may be composed of nickel. In other embodiments, the second conductive material may be composed of a nickel alloy. One of ordinary skill in the art will recognize that second conductive material may be composed of other metals or metal alloys in accordance with one or more embodiments of the present invention. The deposition rate on top of the plated first and second plurality of patterned ink seed layers may be approximately 10 nanometers per minute of second conductive material with a deposited thickness in a range between approximately 0.001 micrometers and approximately 10 micrometers.

In step 640, the substrate may be cleaned with a water treatment configured to remove impurities after the electroless plating process. In certain embodiments, the substrate may be cleaned with water at room temperature. After washing, the substrate may be dried through the application of air, also at room temperature. In certain embodiments, a passivation agent may be sprayed on the substrate to prevent an undesired chemical reaction between the conductive materials and the water.

In step 650, a coating is printed over the first side of the substrate. The coating may be printed by a flexographic printing station with a blank flexographic printing plate. The coating may be a conformal layer of a coating material, instead of ink, that covers the first side of the substrate. In certain embodiments, the coating may have a thickness in a range between approximately 1 micrometer and approximately 50 micrometers over the plated first plurality of patterned ink seed layers. In one or more embodiments of the present invention, the coating may be composed of a scratch and abrasion resistant coating material. In certain embodiments, the coating may be composed of solid content, such as multifunctional monomers and oligomers, with a concentration by weight in a range between approximately 70% and approximately 80%, a photo-initiator with a concentration by weight in a range between approximately 1% and approximately 6%, and a solvent with a concentration by weight in a range between approximately 10% and approximately 30%. In one or more embodiments of the present invention, the coating may be scratch and abrasion resistant and may provide a pencil hardness of at least 6H.

In step 650, the substrate may be cured. In certain embodiments, the substrate may be cured in an oxygen free zone that provides UV radiation with a wavelength in a range between approximately 280 nanometers and 480 nanometers with target intensity in a range between approximately 0.5 mW/cm² and approximately 20 mW/cm² with an exposure time in a range between approximately 0.1 seconds and approximately 10 seconds.

In step 655, a graphic design may be printed on the second side of the substrate. In one or more embodiments of the present invention, the graphic design may be printed in a frame area surrounding the plated second plurality of patterned ink seed layers. The graphic design may be any decorative graphic design suitable for flexographic printing. In certain embodiments, each of one or more color graphics printing stations may print a unique color to achieve a multi-color graphic design. In other embodiments, each of one or more color graphics printing stations may print the same color to provide redundancy and reduce light transmission through the graphic design.

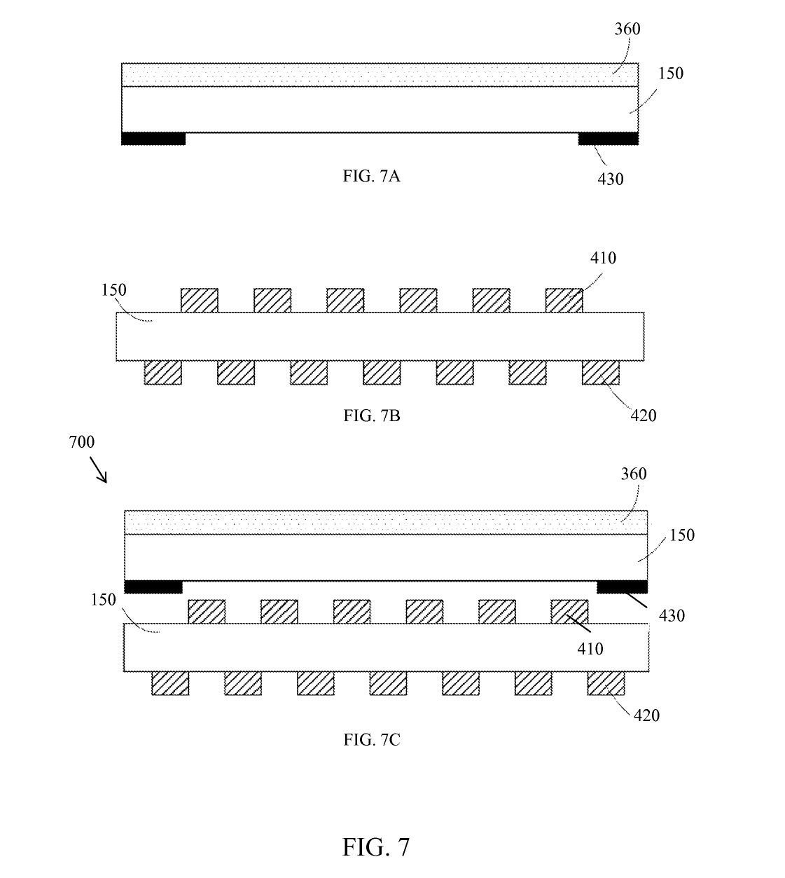

FIGS. 7A-7C show a cross-sectional view of a two-substrate laminated touch sensor 700 in accordance with one or more embodiments of the present invention. In certain embodiments, touch sensor 700 may be manufactured by multi-station flexographic printing system 300 of FIG. 3 in two passes. In FIG. 7A, a coating 360 may be disposed over a first side of a first substrate 150. Coating 360 may be composed of a scratch and abrasion resistant coating material that has a pencil hardness of at least 6H. A graphic design 430 may be disposed in a frame area on a second side of first substrate 150. In FIG. 7B, a first side of a second substrate 150 may include a first plurality of conductive lines 410 formed by a plated first plurality of patterned ink seed layers. In one or more embodiments of the present invention, the plurality of conductive lines 410 may include one or more of x-axis conductive lines, y-axis conductive lines, interconnect conductive lines, and connector conductive lines. In certain embodiments, the plurality of conductive lines 410 may form a conductive pattern design (100 of FIG. 1) on the first side of second substrate 150 as part of touch sensor 700. A second side of the second substrate 150 may include a plurality of conductive lines 420 formed by a plated second plurality of patterned ink seed layers. In one or more embodiments of the present invention, the plurality of conductive lines 420 may include one or more of x-axis conductive lines, y-axis conductive lines, interconnect conductive lines, and connector conductive lines. In certain embodiments, the plurality of conductive lines 420 may form a conductive pattern design (100 of FIG. 1) on the second side of the second substrate 150 as part of touch sensor 700.

In FIG. 7C, the first substrate 150 of FIG. 7A may be laminated to the second substrate 150 of FIG. 7B forming touch sensor 700. The second side of the first substrate 150 may be laminated to the first side of the second substrate 150 with an optically clear adhesive (not shown). In operation, the first side of the first substrate 150, which includes coating 360, faces a user. Because first substrate 150 is transparent, graphic design 430, disposed on the second side of first substrate 150, is visible to the user facing the first side of first substrate 150. As such, graphic design 430 may be viewed through first substrate 150. Because graphic design 430 is disposed on the second side of first substrate 150, when the user interacts with touch sensor 700, the graphic design 430 is not subjected to wear from repeated use.

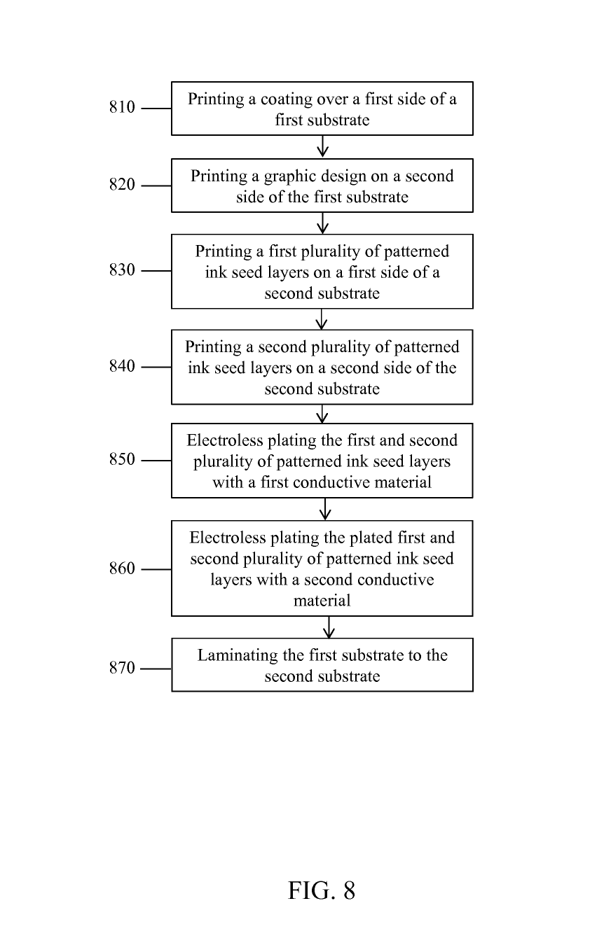

FIG. 8 shows a method of manufacturing a two-substrate laminated touch sensor 700 in accordance with one or more embodiments of the present invention. In certain embodiments, touch sensor 700 may be manufactured by multi-station flexographic printing system 300 of FIG. 3 in two passes.

In a first manufacturing pass, a first substrate may be cleaned to prepare it for flexographic printing. The first substrate may be a flexible and transparent substrate composed of PET, PEN, TAC, acrylic, epoxy, polyimide, polyurethane, polycarbonate, cycloolefin polymers, glass, or combinations thereof. In certain embodiments, the first substrate may have a thickness in a range between approximately 1 micrometer and approximately 1 millimeter. In certain embodiments, the first substrate may be cleaned with a high electric field ozone generator configured to remove impurities, such as oil or grease, from the surface of the substrate prior to printing. In other embodiments, the first substrate may be cleaned with a deionized air shower. The first substrate may also be cleaned by a web cleaner configured to remove particulate matter, contaminants, and other impurities. One of ordinary skill in the art will recognize that the first substrate may be cleaned by other processes in accordance with one or more embodiments of the present invention.

In step 810, a coating is printed over the first side of the first substrate. The coating may be printed by a flexographic printing station with a blank flexographic printing plate. The coating may be a conformal layer of a coating material, instead of ink, that covers the first side of the first substrate. In certain embodiments, the coating may have a thickness in a range between approximately 1 micrometer and approximately 50 micrometers over the plated first plurality of patterned ink seed layers. In one or more embodiments of the present invention, the coating may be composed of a scratch and abrasion resistant coating material. In certain embodiments, the coating may be composed of solid content, such as multifunctional monomers and oligomers, with a concentration by weight in a range between approximately 70% and approximately 80%, a photo-initiator with a concentration by weight in a range between approximately 1% and approximately 6%, and a solvent with a concentration by weight in a range between approximately 10% and approximately 30%. In one or more embodiments of the present invention, the coating may be scratch and abrasion resistant and may provide a pencil hardness of at least 6H. After coating, the first substrate may be cured. In certain embodiments, the substrate may be cured in an oxygen free zone that provides UV radiation with a wavelength in a range between approximately 280 nanometers and 480 nanometers with target intensity in a range between approximately 0.5 mW/cm² and approximately 20 mW/cm² with an exposure time in a range between approximately 0.1 seconds and approximately 5 seconds.

In step 820, a graphic design may be printed on the second side of the first substrate. In one or more embodiments of the present invention, the graphic design may be printed in a frame area surrounding a plated second plurality of patterned ink seed layers. The graphic design may be any decorative graphic design suitable for flexographic printing. In certain embodiments, each of one or more color graphics printing stations may print a unique color to achieve a multi-color graphic design. In other embodiments, each of one or more color graphics printing stations may print the same color to provide redundancy and reduce light transmission through the graphic design.

In a second manufacturing pass, a second substrate may be cleaned to prepare it for flexographic printing. The second substrate may be a flexible and transparent substrate composed of PET, PEN, TAC, acrylic, epoxy, polyimide, polyurethane, polycarbonate, cycloolefin polymers, glass, or combinations thereof. In certain embodiments, the second substrate may have a thickness in a range between approximately 1 micrometer and approximately 1 millimeter. In certain embodiments, the second substrate may be cleaned with a high electric field ozone generator configured to remove impurities, such as oil or grease, from the surface of the substrate prior to printing. In other embodiments, the second substrate may be cleaned with a deionized air shower. The second substrate may also be cleaned by a web cleaner configured to remove particulate matter, contaminants, and other impurities. One of ordinary skill in the art will recognize that the second substrate may be cleaned by other processes in accordance with one or more embodiments of the present invention.

In step 830, a first plurality of patterned ink seed layers may be printed on a first side of the second substrate. The first plurality of patterned ink seed layers may include a plurality of x-axis seed lines, a plurality of y-axis seed lines, a plurality of interconnect seed lines, and a plurality of connector seed lines. In one or more embodiments of the present invention, one or more of the plurality of x-axis seed lines and one or more of the plurality of y-axis seed lines may have a width less than 10 micrometers. In certain embodiments, one or more of x-axis seed lines, y-axis seed lines, interconnect seed lines, and connector seed lines may be printed by a separate flexographic printing station. For example, in certain embodiments, a first flexographic printing station may be used to print the plurality of x-axis seed lines, a second flexographic printing station may be used to print the plurality of y-axis seed lines, a third flexographic printing station may be used to print the plurality of interconnect seed lines, and a fourth flexographic printing station may be used to print the plurality of connector seed lines in a predetermined sequence. In other embodiments, the third flexographic printing station may be used to print the plurality of interconnect seed lines and the plurality of connector seed lines. One of ordinary skill in the art will recognize that the number of flexographic printing stations used to print on the first side of the second substrate may vary in accordance with one or more embodiments of the present invention. In certain embodiments, the flexographic printing stations may be sequenced to print smaller lines or features before larger lines or features. The first plurality of patterned ink seed layers may be printed with a catalytic ink or catalytic alloy ink. As a result, the first plurality of patterned ink seed layers may serve as plating seed lines suitable for metallization by an electroless plating process.

The second substrate may be cured to polymerize the printed first plurality of patterned ink seed layers on the first side of the second substrate. The second substrate may be cured by UV radiation with a wavelength in a range between approximately 280 nanometers and 480 nanometers with target intensity in a range between approximately 0.5 mW/cm² and approximately 50 mW/cm² with an exposure time in a range between approximately 0.1 seconds and approximately 5 seconds. As part of curing, the second substrate may then be soft-baked in a pass-through oven that applies heat in a temperature range between approximately 20 degrees Celsius and approximately 85 degrees Celsius for a period of time in a range between approximately 1 second to approximately 10 seconds.

In step 840, a second plurality of patterned ink seed layers may be printed on a second side of the second substrate. The second plurality of patterned ink seed layers may include a plurality of x-axis seed lines, a plurality of y-axis seed lines, a plurality of interconnect seed lines, and a plurality of connector seed lines. In one or more embodiments of the present invention, one or more of the plurality of x-axis seed lines and one or more of the plurality of y-axis seed lines may have a width less than 10 micrometers. In certain embodiments, one or more of x-axis seed lines, y-axis seed lines, interconnect seed lines, and connector seed lines may be printed by a separate flexographic printing station. For example, in certain embodiments, a first flexographic printing station may be used to print the plurality of x-axis seed lines, a second flexographic printing station may be used to print the plurality of y-axis seed lines, a third flexographic printing station may be used to print the plurality of interconnect seed lines, and a fourth flexographic printing station may be used to print the plurality of connector seed lines in a predetermined sequence. In other embodiments, the third flexographic printing station may be used to print the plurality of interconnect seed lines and the plurality of connector seed lines. One of ordinary skill in the art will recognize that the number of flexographic printing stations used to print on the second side of the second substrate may vary in accordance with one or more embodiments of the present invention. In certain embodiments, the flexographic printing stations may be sequenced to print smaller lines or features before larger lines or features. The second plurality of patterned ink seed layers may be printed with a catalytic ink or catalytic alloy ink. As a result, the second plurality of patterned ink seed layers may serve as plating seed lines suitable for metallization by an electroless plating process.

The second substrate may be cured to polymerize the printed second plurality of patterned ink seed layers on the second side of the second substrate. The second substrate may be cured by UV radiation with a wavelength in a range between approximately 280 nanometers and 480 nanometers with target intensity in a range between approximately 0.5 mW/cm² and approximately 50 mW/cm² with an exposure time in a range between approximately 0.1 seconds and approximately 5 seconds. As part of curing, the second substrate may then be soft-baked in a pass-through oven that applies heat in a temperature range between approximately 20 degrees Celsius and approximately 85 degrees Celsius for a period of time in a range between approximately 1 second to approximately 10 seconds.

In step 850, the first plurality of patterned ink seed layers and the second plurality of patterned ink seed layers may be electroless plated with a first conductive material. The second substrate may be submerged in an electroless plating tank that includes a first conductive material in a liquid state at a temperature in a range between approximately 20 degrees Celsius and approximately 90 degrees Celsius. In certain embodiments, the first conductive material may be in a liquid state at a temperature of approximately 45 degrees Celsius. In certain embodiments, the first conductive material may be composed of copper. In other embodiments, the first conductive material may be composed of a copper alloy. One of ordinary skill in the art will recognize that the first conductive material may be composed of other metals or metal alloys in accordance with one or more embodiments of the present invention. The deposition rate on top of the first and second plurality of patterned ink seed layers may be approximately 10 nanometers per minute of first conductive material with a deposited thickness in a range between approximately 0.001 micrometers and approximately 10 micrometers.

In step 860, the plated first plurality of patterned ink seed layers and the plated second plurality of patterned ink seed layers may be electroless plated with a second conductive material. The second substrate may be submerged in an electroless plating tank that includes a second conductive material in a liquid state at a temperature in a range between approximately 20 degrees Celsius and approximately 90 degrees Celsius. In certain embodiments, the second conductive material may be in a liquid state at a temperature of approximately 45 degrees Celsius. In certain embodiments, the second conductive material may be composed of nickel. In other embodiments, the second conductive material may be composed of a nickel alloy. One of ordinary skill in the art will recognize that second conductive material may be composed of other metals or metal alloys in accordance with one or more embodiments of the present invention. The deposition rate on top of the plated first and second plurality of patterned ink seed layers may be approximately 10 nanometers per minute of second conductive material with a deposited thickness in a range between approximately 0.001 micrometers and approximately 10 micrometers.

The second substrate may be cleaned with a water treatment configured to remove impurities after the electroless plating process. In certain embodiments, the second substrate may be cleaned with water at room temperature. After washing, the second substrate may be dried through the application of air, also at room temperature. In certain embodiments, a passivation agent may be sprayed on the second substrate to prevent an undesired chemical reaction between the conductive materials and the water.

In step 870, the first substrate may be laminated to the second substrate. The second side of the first substrate may be laminated to the first side of the second substrate with an optically clear adhesive.

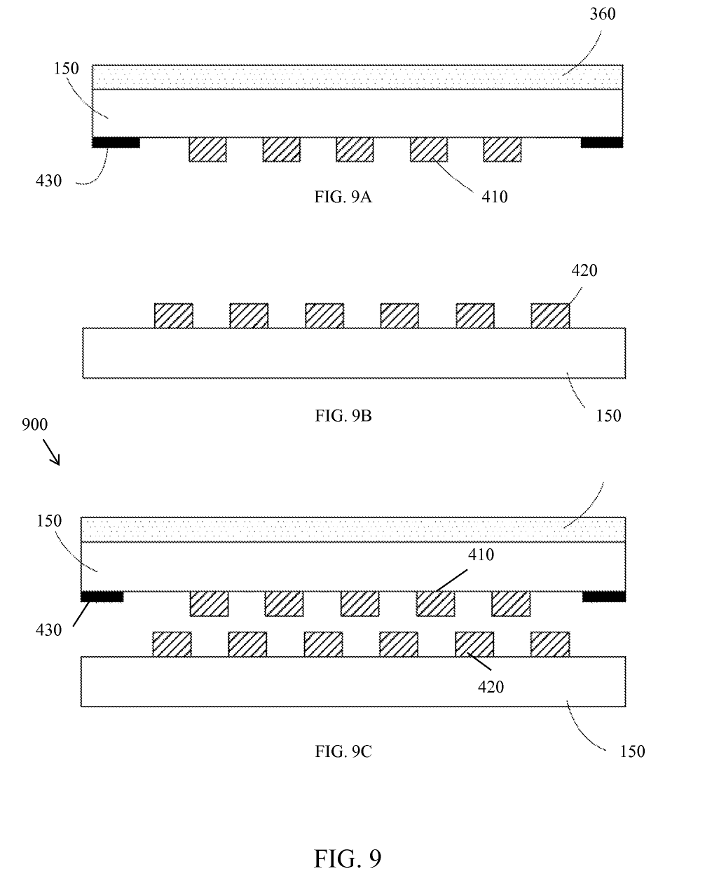

FIGS. 9A-9C show a cross-sectional view of a two-substrate laminated touch sensor 900 in accordance with one or more embodiments of the present invention. In certain embodiments, touch sensor 900 may be manufactured by multi-station flexographic printing system 300 of FIG. 3 in two passes. In FIG. 9A, a coating 360 may be disposed over a first side of a first substrate 150. Coating 360 may be composed of a scratch and abrasion resistant coating material that has a pencil hardness of at least 6H. A second side of the first substrate 150 may include a first plurality of conductive lines 410 formed by a plated first plurality of patterned ink seed layers. In one or more embodiments of the present invention, the plurality of conductive lines 410 may include one or more of x-axis conductive lines, y-axis conductive lines, interconnect conductive lines, and connector conductive lines. In certain embodiments, the plurality of conductive lines 410 may form a conductive pattern design (100 of FIG. 1) on the second side of the first substrate 150 as part of touch sensor 900. A graphic design 430 may be disposed in a frame area on the second side of first substrate 150.

In FIG. 9B, a first side of a second substrate 150 may include a plurality of conductive lines 420 formed by a plated second plurality of patterned ink seed layers. In one or more embodiments of the present invention, the plurality of conductive lines 420 may include one or more of x-axis conductive lines, y-axis conductive lines, interconnect conductive lines, and connector conductive lines. In certain embodiments, the plurality of conductive lines 420 may form a conductive pattern design (100 of FIG. 1) on the first side of the second substrate 150 as part of touch sensor 900.

In FIG. 9C, the first substrate 150 of FIG. 9A may be laminated to the second substrate 150 of FIG. 9B forming touch sensor 900. The second side of the first substrate 150 may be laminated to the first side of the second substrate 150 with an optically clear adhesive (not shown). In operation, the first side of the first substrate 150, which includes coating 360, faces a user. Because first substrate 150 is transparent, graphic design 430, disposed on the second side of first substrate 150, is visible to the user facing the first side of first substrate 150. As such, graphic design 430 may be viewed through first substrate 150. Because graphic design 430 is disposed on the second side of first substrate 150, when the user interacts with touch sensor 900, the graphic design 430 is not subjected to wear from repeated use.

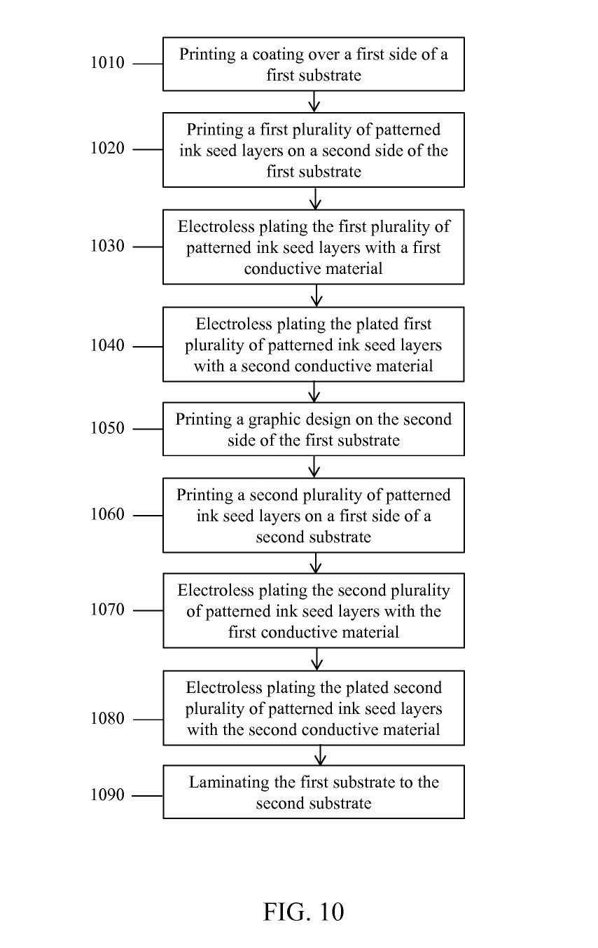

FIG. 10 shows a method of manufacturing a two-substrate laminated touch sensor 900 in accordance with one or more embodiments of the present invention. In certain embodiments, touch sensor 900 may be manufactured by multi-station flexographic printing system 300 of FIG. 3 in two passes.

In a first manufacturing pass, a first substrate may be cleaned to prepare it for flexographic printing. The first substrate may be a flexible and transparent substrate composed of PET, PEN, TAC, acrylic, epoxy, polyimide, polyurethane, polycarbonate, cycloolefin polymers, glass, or combinations thereof. In certain embodiments, the first substrate may have a thickness in a range between approximately 1 micrometer and approximately 1 millimeter. In certain embodiments, the first substrate may be cleaned with a high electric field ozone generator configured to remove impurities, such as oil or grease, from the surface of the substrate prior to printing. In other embodiments, the first substrate may be cleaned with a deionized air shower. The first substrate may also be cleaned by a web cleaner configured to remove particulate matter, contaminants, and other impurities. One of ordinary skill in the art will recognize that the first substrate may be cleaned by other processes in accordance with one or more embodiments of the present invention.

In step 1010, a coating is printed over the first side of the first substrate. The coating may be printed by a flexographic printing station with a blank flexographic printing plate. The coating may be a conformal layer of a coating material, instead of ink, that covers the first side of the first substrate. In certain embodiments, the coating may have a thickness in a range between approximately 1 micrometer and approximately 50 micrometers over a plated first plurality of patterned ink seed layers. In one or more embodiments of the present invention, the coating may be composed of a scratch and abrasion resistant coating material. In certain embodiments, the coating may be composed of solid content, such as multifunctional monomers and oligomers, with a concentration by weight in a range between approximately 70% and approximately 80%, a photo-initiator with a concentration by weight in a range between approximately 1% and approximately 6%, and a solvent with a concentration by weight in a range between approximately 10% and approximately 30%. In one or more embodiments of the present invention, the coating may be scratch and abrasion resistant and may provide a pencil hardness of at least 6H. After coating, the first substrate may be cured. In certain embodiments, the substrate may be cured in an oxygen free zone that provides UV radiation with a wavelength in a range between approximately 280 nanometers and 480 nanometers with target intensity in a range between approximately 0.5 mW/cm² and approximately 20 mW/cm² with an exposure time in a range between approximately 0.1 seconds and approximately 5 seconds.

In step 1020, a first plurality of patterned ink seed layers may be printed on a second side of the first substrate. The first plurality of patterned ink seed layers may include a plurality of x-axis seed lines, a plurality of y-axis seed lines, a plurality of interconnect seed lines, and a plurality of connector seed lines. In one or more embodiments of the present invention, one or more of the plurality of x-axis seed lines and one or more of the plurality of y-axis seed lines may have a width less than 10 micrometers. In certain embodiments, one or more of x-axis seed lines, y-axis seed lines, interconnect seed lines, and connector seed lines may be printed by a separate flexographic printing station. For example, in certain embodiments, a first flexographic printing station may be used to print the plurality of x-axis seed lines, a second flexographic printing station may be used to print the plurality of y-axis seed lines, a third flexographic printing station may be used to print the plurality of interconnect seed lines, and a fourth flexographic printing station may be used to print the plurality of connector seed lines in a predetermined sequence. In other embodiments, the third flexographic printing station may be used to print the plurality of interconnect seed lines and the plurality of connector seed lines. One of ordinary skill in the art will recognize that the number of flexographic printing stations used to print on the second side of the first substrate may vary in accordance with one or more embodiments of the present invention. In certain embodiments, the flexographic printing stations may be sequenced to print smaller lines or features before larger lines or features. The first plurality of patterned ink seed layers may be printed with a catalytic ink or catalytic alloy ink. As a result, the first plurality of patterned ink seed layers may serve as plating seed lines suitable for metallization by an electroless plating process.

The first substrate may be cured to polymerize the printed first plurality of patterned ink seed layers on the second side of the first substrate. The first substrate may be cured by UV radiation with a wavelength in a range between approximately 280 nanometers and 480 nanometers with target intensity in a range between approximately 0.5 mW/cm² and approximately 50 mW/cm² with an exposure time in a range between approximately 0.1 seconds and approximately 5 seconds. As part of curing, the first substrate may then be soft-baked in a pass-through oven that applies heat in a temperature range between approximately 20 degrees Celsius and approximately 85 degrees Celsius for a period of time in a range between approximately 1 second to approximately 10 seconds.

In step 1030, the first plurality of patterned ink seed layers may be electroless plated with a first conductive material. The first substrate may be submerged in an electroless plating tank that includes a first conductive material in a liquid state at a temperature in a range between approximately 20 degrees Celsius and approximately 90 degrees Celsius. In certain embodiments, the first conductive material may be a liquid at a temperature of approximately 45 degrees Celsius. In certain embodiments, the first conductive material may be composed of copper. In other embodiments, the first conductive material may be composed of a copper alloy. One of ordinary skill in the art will recognize that the first conductive material may be composed of other metals or metal alloys in accordance with one or more embodiments of the present invention. The deposition rate on top of the first plurality of patterned ink seed layers may be approximately 10 nanometers per minute of first conductive material with a deposited thickness in a range between approximately 0.001 micrometers and approximately 10 micrometers.

In step 1040, the plated first plurality of patterned ink seed layers may be electroless plated with a second conductive material. The first substrate may be submerged in an electroless plating tank that includes a second conductive material in a liquid state at a temperature in a range between approximately 20 degrees Celsius and approximately 90 degrees Celsius. In certain embodiments, the second conductive material may be a liquid at a temperature of approximately 45 degrees Celsius. In certain embodiments, the second conductive material may be composed of nickel. In other embodiments, the second conductive material may be composed of a nickel alloy. One of ordinary skill in the art will recognize that second conductive material may be composed of other metals or metal alloys in accordance with one or more embodiments of the present invention. The deposition rate on top of the plated first plurality of patterned ink seed layers may be approximately 10 nanometers per minute of second conductive material with a deposited thickness in a range between approximately 0.001 micrometers and approximately 10 micrometers.

The first substrate may be cleaned with a water treatment configured to remove impurities after the electroless plating process. In certain embodiments, the first substrate may be cleaned with water at room temperature. After washing, the first substrate may be dried through the application of air, also at room temperature. In certain embodiments, a passivation agent may be sprayed on the first substrate to prevent an undesired chemical reaction between the conductive materials and the water.

In step 1050, a graphic design may be printed on the second side of the first substrate. In one or more embodiments of the present invention, the graphic design may be printed in a frame area surrounding a plated first plurality of patterned ink seed layers. The graphic design may be any decorative graphic design suitable for flexographic printing. In certain embodiments, each of one or more color graphics printing stations may print a unique color to achieve a multi-color graphic design. In other embodiments, each of one or more color graphics printing stations may print the same color to provide redundancy and reduce light transmission through the graphic design.

In a second manufacturing pass, a second substrate may be cleaned to prepare it for flexographic printing. The second substrate may be a flexible and transparent substrate composed of PET, PEN, TAC, acrylic, epoxy, polyimide, polyurethane, polycarbonate, cycloolefin polymers, glass, or combinations thereof. In certain embodiments, the second substrate may have a thickness in a range between approximately 1 micrometer and approximately 1 millimeter. In certain embodiments, the second substrate may be cleaned with a high electric field ozone generator configured to remove impurities, such as oil or grease, from the surface of the substrate prior to printing. In other embodiments, the seconds substrate may be cleaned with a deionized air shower. The second substrate may also be cleaned by a web cleaner configured to remove particulate matter, contaminants, and other impurities. One of ordinary skill in the art will recognize that the second substrate may be cleaned by other processes in accordance with one or more embodiments of the present invention.

In step 1060, a second plurality of patterned ink seed layers may be printed on a first side of the second substrate. The second plurality of patterned ink seed layers may include a plurality of x-axis seed lines, a plurality of y-axis seed lines, a plurality of interconnect seed lines, and a plurality of connector seed lines. In one or more embodiments of the present invention, one or more of the plurality of x-axis seed lines and one or more of the plurality of y-axis seed lines may have a width less than 10 micrometers. In certain embodiments, one or more of x-axis seed lines, y-axis seed lines, interconnect seed lines, and connector seed lines may be printed by a separate flexographic printing station. For example, in certain embodiments, a first flexographic printing station may be used to print the plurality of x-axis seed lines, a second flexographic printing station may be used to print the plurality of y-axis seed lines, a third flexographic printing station may be used to print the plurality of interconnect seed lines, and a fourth flexographic printing station may be used to print the plurality of connector seed lines in a predetermined sequence. In other embodiments, the third flexographic printing station may be used to print the plurality of interconnect seed lines and the plurality of connector seed lines. One of ordinary skill in the art will recognize that the number of flexographic printing stations used to print on the first side of the second substrate may vary in accordance with one or more embodiments of the present invention. In certain embodiments, the flexographic printing stations may be sequenced to print smaller lines or features before larger lines or features. The second plurality of patterned ink seed layers may be printed with a catalytic ink or catalytic alloy ink. As a result, the second plurality of patterned ink seed layers may serve as plating seed lines suitable for metallization by an electroless plating process.

The second substrate may be cured to polymerize the printed second plurality of patterned ink seed layers on the first side of the second substrate. The second substrate may be cured by UV radiation with a wavelength in a range between approximately 280 nanometers and 480 nanometers with target intensity in a range between approximately 0.5 mW/cm² and approximately 50 mW/cm² with an exposure time in a range between approximately 0.1 seconds and approximately 5 seconds. As part of curing, the second substrate may then be soft-baked in a pass-through oven that applies heat in a temperature range between approximately 20 degrees Celsius and approximately 85 degrees Celsius for a period of time in a range between approximately 1 second to approximately 10 seconds.

In step 1070, the second plurality of patterned ink seed layers may be electroless plated with a first conductive material. The second substrate may be submerged in an electroless plating tank that includes a first conductive material in a liquid state at a temperature in a range between approximately 20 degrees Celsius and approximately 90 degrees Celsius. In certain embodiments, the first conductive material may be a liquid at a temperature of approximately 45 degrees Celsius. In certain embodiments, the first conductive material may be composed of copper. In other embodiments, the first conductive material may be composed of a copper alloy. One of ordinary skill in the art will recognize that the first conductive material may be composed of other metals or metal alloys in accordance with one or more embodiments of the present invention. The deposition rate on top of the second plurality of patterned ink seed layers may be approximately 10 nanometers per minute of first conductive material with a deposited thickness in a range between approximately 0.001 micrometers and approximately 10 micrometers.

In step 1080, the plated second plurality of patterned ink seed layers may be electroless plated with a second conductive material. The second substrate may be submerged in an electroless plating tank that includes a second conductive material in a liquid state at a temperature in a range between approximately 20 degrees Celsius and approximately 90 degrees Celsius. In certain embodiments, the second conductive material may be a liquid at a temperature of approximately 80 degrees Celsius. In certain embodiments, the second conductive material may be composed of nickel. In other embodiments, the second conductive material may be composed of a nickel alloy. One of ordinary skill in the art will recognize that second conductive material may be composed of other metals or metal alloys in accordance with one or more embodiments of the present invention. The deposition rate on top of the plated second plurality of patterned ink seed layers may be approximately 10 nanometers per minute of second conductive material with a deposited thickness in a range between approximately 0.001 micrometers and approximately 10 micrometers.

The second substrate may be cleaned with a water treatment configured to remove impurities after the electroless plating process. In certain embodiments, the second substrate may be cleaned with water at room temperature. After washing, the second substrate may be dried through the application of air, also at room temperature. In certain embodiments, a passivation agent may be sprayed on the second substrate to prevent an undesired chemical reaction between the conductive materials and the water.

In step 1090, the first substrate may be laminated to the second substrate. The second side of the first substrate may be laminated to the first side of the second substrate with an optically clear adhesive.

Advantages of one or more embodiments of the present invention may include one or more of the following:

In one or more embodiments of the present invention, a single-substrate integrated touch sensor may be manufactured with a roll-to-roll flexographic printing process.

In one or more embodiments of the present invention, a single-substrate integrated touch sensor may be manufactured in a single pass of a flexographic printing process.

In one or more embodiments of the present invention, a single-substrate integrated touch sensor may be scratch and abrasion resistant with a pencil hardness of at least 6H.

In one or more embodiments of the present invention, a single-substrate integrated touch sensor may have a conductive pattern design that includes one or more lines having a width of less than 10 micrometers.

In one or more embodiments of the present invention, a single-substrate integrated touch sensor may have a conductive pattern design that includes one or more lines having a width in a range between approximately 10 micrometers and approximately 100 micrometers.

In one or more embodiments of the present invention, a single-substrate integrated touch sensor may include decorative color graphics in a frame area outside of the conductive pattern design. In one or more embodiments of the present invention, a method of manufacturing a single-substrate integrated touch sensor simplifies manufacturing processes.

In one or more embodiments of the present invention, a method of manufacturing a single-substrate integrated touch sensor improves manufacturing efficiency.

In one or more embodiments of the present invention, a method of manufacturing a single-substrate integrated touch sensor reduces manufacturing waste.

In one or more embodiments of the present invention, a method of manufacturing a single-substrate integrated touch sensor is less expensive than conventional touch sensor fabrication processes.

In one or more embodiments of the present invention, a method of manufacturing a single-substrate integrated touch sensor is compatible with flexographic printing processes.

In one or more embodiments of the present invention, a two-substrate laminated touch sensor may be manufactured with a roll-to-roll flexographic printing process.

In one or more embodiments of the present invention, a two-substrate laminated touch sensor may be manufactured in a two passes of a flexographic printing process.

In one or more embodiments of the present invention, a two-substrate laminated touch sensor may be scratch and abrasion resistant with a pencil hardness of at least 6H.

In one or more embodiments of the present invention, a two-substrate laminated touch sensor may have a conductive pattern design that includes one or more lines having a width of less than 10 micrometers.

In one or more embodiments of the present invention, a two-substrate laminated touch sensor may have a conductive pattern design that includes one or more lines having a width in a range between approximately 10 micrometers and approximately 100 micrometers.

In one or more embodiments of the present invention, a two-substrate laminated touch sensor may include decorative color graphics in a frame area outside of the conductive pattern design. In one or more embodiments of the present invention, a method of manufacturing a two-substrate laminated touch sensor simplifies manufacturing processes.

In one or more embodiments of the present invention, a method of manufacturing a two-substrate laminated touch sensor improves manufacturing efficiency.

In one or more embodiments of the present invention, a method of manufacturing a two-substrate laminated touch sensor reduces manufacturing waste.

In one or more embodiments of the present invention, a method of manufacturing a two-substrate laminated touch sensor is less expensive than conventional touch sensor fabrication processes.

In one or more embodiments of the present invention, a method of manufacturing a two-substrate laminated touch sensor is compatible with flexographic printing processes.

While the present invention has been described with respect to the above-noted embodiments, those skilled in the art, having the benefit of this disclosure, will recognize that other embodiments may be devised that are within the scope of the invention as disclosed herein. Accordingly, the scope of the invention should be limited only by the appended claims.

What is claimed is:

1. A method of manufacturing comprising:
printing a first plurality of patterned ink seed layers on a first side of a substrate;
printing a second plurality of patterned ink seed layers on a second side of the substrate;
electroless plating the first plurality of patterned ink seed layers and the second plurality of patterned ink seed layers with a first conductive material;
printing a coating over the first side of the substrate; and
printing a graphic design on the second side of the substrate.

2. The method of claim 1, further comprising:
cleaning the substrate with a high electric field ozone generator; and
cleaning the substrate with a web cleaner.

3. The method of claim 1, further comprising:
curing the substrate after printing the first plurality of patterned ink seed layers; and
curing the substrate after printing the second plurality of patterned ink seed layers.

4. The method of claim 1, further comprising:
electroless plating the plated first plurality of patterned ink seed layers and the plated second plurality of patterned ink seed layers with a second conductive material.

5. The method of claim 1, further comprising:
cleaning the substrate with a water treatment.

6. The method of claim 1, further comprising:
curing the substrate after printing the coating over the first side of the substrate.

7. The method of claim 1, wherein the first plurality patterned ink seed layers and the second plurality of patterned ink seed layers comprise catalytic ink.

8. The method of claim 1, wherein the substrate comprises polyethylene terephthalate.

9. The method of claim 1, wherein the first conductive material comprises copper.

10. The method of claim 4, wherein the second conductive material comprises nickel.

11. The method of claim 1, wherein the coating comprises a scratch and abrasion resistant coating material.

12. The method of claim 1, wherein the applied coating has a pencil hardness of at least 6H.

13. The method of claim 1, wherein one or more patterned ink seed layers of the first plurality of patterned ink seed layers and one or more patterned ink seed layers of the second plurality of patterned ink seed layers have a width less than approximately 10 micrometers.

14. The method of claim 1, wherein one or more patterned ink seed layers of the first plurality of patterned ink seed layers and one or more patterned ink seed layers of the second plurality of patterned ink seed layers have a width in a range between approximately 10 micrometers and approximately 100 micrometers.

15. The method of claim 1, wherein one or more flexographic printing stations print the first plurality of patterned ink seed layers on the first side of the substrate.

16. The method of claim 1, wherein one or more flexographic printing stations print the second plurality of patterned ink seed layers on the second side of the substrate.

17. The method of claim 1, wherein one or more flexographic printing stations print the graphic design on the second side of the substrate.

18. The method of claim 1, wherein the graphic design is disposed in a frame area surrounding the plated second plurality of patterned seed layers.

19. A method of manufacturing comprising:
printing a coating over a first side of a first substrate;
printing a graphic design on a second side of the first substrate;
printing a first plurality of patterned ink seed layers on a first side of a second substrate;
printing a second plurality of patterned ink seed layers on a second side of the second substrate;
electroless plating the first plurality of patterned ink seed layers and the second plurality of patterned ink seed layers of the second substrate with a first conductive material; and
laminating the first substrate to the second substrate.

20. A method of manufacturing comprising:
printing a coating over a first side of a first substrate;
printing a first plurality of patterned ink seed layers on a second side of the first substrate;
electroless plating the first plurality of patterned ink seed layers of the first substrate with a first conductive material;
printing a graphic design on the second side of the first substrate;
printing a second plurality of patterned ink seed layers on a first side of a second substrate;
electroless plating the second plurality of patterned ink seed layers of the second substrate with the first conductive material; and
laminating the first substrate to the second substrate.
